(19) United States
(12) Patent Application Publication
(10) Pub. No.: US 2006/0044873 A1
(43) Pub. Date: Mar. 2, 2006

(54) Semiconductor device and a method of manufacturing the same

(75) Inventors: Kozo Katayama, Tokyo (JP); Digh Hisamoto, Kokubunji (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/186,877

(22) Filed: Jul. 22, 2005

(30) Foreign Application Priority Data
Aug. 26, 2004 (JP) 2004-246200

(51) Int. Cl. G11C 16/04

(52) U.S. Cl. 365/185.18

(57) ABSTRACT

A semiconductor device including an SOI substrate and a MONOS type nonvolatile memory cell with a first drain composed of an n⁺ type diffusion region and a second drain composed of a p⁺ type diffusion region, wherein the first and second drains are arranged in different planar locations in a silicon layer of the SOI substrate. In the data write operation of the device, electrons are injected from the first drain, and then hot electrons created by a strong electric field between a control gate and a memory gate of the memory cell are injected into a charge storage layer. In the data erase operation of the device, holes are injected from the second drain, and then hot holes created by a strong electric field between the control gate and the memory gate are injected into the charge storage layer. The semiconductor device can reduce current consumption for erasing data.

### CROSS-REFERENCE TO RELATED APPLICATION

The present application claims priority from Japanese patent application No. 2004-246200 filed on Aug. 26, 2004, the content of which is hereby incorporated by reference into this application.

### BACKGROUND OF THE INVENTION

1. Field of the Invention

The present invention relates to a semiconductor device and a method of manufacturing the same. More specifically, it relates to a technique useful in application to a semiconductor device having a MONOS (Metal Oxide Nitride Oxide Semiconductor) type nonvolatile memory cell.

2. Description of the Related Art

In regard to electrically rewritable nonvolatile memories such as an EEPROM (Electrically Erasable Programmable Read Only Memory) and a flash memory, a program is rewritable on-board. This makes the following possible: to handle limited production of a wide variety of products, to tune products on an individual destination basis, to update a program after shipment, etc. in addition to shorten development periods and to improve development efficiencies. Therefore, the range of application of electrically rewritable nonvolatile memories is widening in various uses. Especially in recent years, the need for microcomputers having a built-in MPU (Micro Processing Unit) and a built-in EEPROM (or flash memory) has been growing.

In regard to electrically rewritable nonvolatile memories, MONOS structure in which a nitride film is used as a charge storage layer has been in the spotlight in recent years. In this case, the charge contributing to data storage is accumulated in a discrete trap of the nitride film, which is an isolator. On this account, even when a defect arises somewhere in an oxide film surrounding an accumulation node to cause an abnormal leakage, the charge stored in the charge storage layer never completely runs out from there. Therefore, it is possible to improve the reliability of data holding.

In regard to the arrangement of a MONOS type memory cell, there has been proposed a memory cell having a single-transistor structure. A memory cell of this structure is prone to be affected by a disturbance, for example, in comparison to a memory cell of EEPROM cell structure. Therefore, a split-gate type memory cell having a two-transistor structure with a control gate provided therein has been also proposed. As for this kind of split-gate type memory cell, the following are feasible depending on the process to stack one of the gates on the other gate, for example: control gate stacked type memory cells; memory gate stacked type memory cells; and memory gate stacked type memory cells for which the side-wall scheme is adopted.

For example, U.S. Pat. No. 5,969,383 discloses an EEPROM device including a split-gate FET, in which the split-gate FET has a source, a drain, a control gate adjacent to the drain, and a memory gate adjacent to the source.

In addition, U.S. Pat. No. 5,346,834 discloses a FinFET that adopts a memory cell configuration. The FinFET has an insulating substrate, a source and a drain, formed in a rectangular parallelepiped shape, a channel coupling the source with the drain, and a gate wrapping the channel from the both sides thereof with an insulating film placed between the channel and the gate.

### SUMMARY OF THE INVENTION

A MONOS type memory cell of the split-gate structure having a control gate and a memory gate provided therein poses various technical problems, details of which are to be described later.

It is an object of the invention to provide a technique for a semiconductor device having a MONOS type nonvolatile memory cell, which enables the reduction in current consumption during the time of erasing data.

It is another object of the invention to provide a technique for a semiconductor device having a MONOS type nonvolatile memory cell, which can prevent data from being left after erasure thereby to diminish the degradation of data in rewriting.

The above and other objects of the invention and novel features thereof will be apparent from the description herein and the accompanying drawings.

Of the aspects of the invention herein disclosed, the outline of representative ones can be described in brief as follow.

A semiconductor device according to the invention has a MONOS type memory cell including a first drain comprised of an n⁺ type diffusion region and a second drain comprised of a p⁺ type diffusion region, and the first and second drains are respectively formed in different planar locations in a silicon layer that the semiconductor substrate includes. In the semiconductor device, data is written by injecting electrons from the first drain of the memory cell, and injecting hot electrons created by a strong electric field between the control gate and the memory gate into a charge storage layer of the memory cell. And, data is erased by injecting holes from the second drain of the memory cell, and injecting hot holes created by a strong electric field between the control gate and the memory gate into the charge storage layer.

A method of manufacturing a semiconductor device according to the invention includes the steps of:

forming a gate-insulating film in a first region on a main surface of said semiconductor substrate;

forming a control gate of a field effect transistor for selecting a memory cell in the first region so as to overlie the gate-insulating film;

forming a multilayer insulating film in a second region adjacent to the first region, the multilayer film composed of an insulating film making a bottom layer, a charge storage layer and an insulating film making a top layer;

forming a memory gate of a field effect transistor for memory in the second region so as to overlie the multilayer insulating film;

introducing an n type impurity into a region adjacent to the field effect transistor for selecting a memory cell and a region adjacent to the field effect transistor for memory to form n⁺ diffusion regions; and

introducing a p type impurity into a region adjacent to the field effect transistor for selecting a memory cell to form a p⁺ type diffusion region different in planar location from an n⁺ type diffusion region.

Of the aspects of the invention herein disclosed, the effect offered by the representative ones can be described in brief as follow.

It becomes possible to realize a MONOS type nonvolatile memory cell, which enables the reduction in current consumption for erasing data and which can prevent data from being left after erasure thereby to diminish the degradation of data in rewriting.

### BRIEF DESCRIPTION OF THE DRAWINGS

FIG. 1 is a circuit diagram of a MONOS type memory cell according to the first embodiment of the invention;

FIG. 2 is a plan view of an important portion of the MONOS type memory cell according to the first embodiment;

FIGS. 3A, 3B are partial sectional views of the important portion of the MONOS type memory cell respectively taken along the lines A-A′ and B-B′ in FIG. 2;

FIG. 4 is a plan view of an important portion of a modification of the MONOS type memory cell according to the first embodiment;

FIG. 5 is a view of a NOR type array constructed of MONOS type memory cells according to the first embodiment;

FIGS. 6A, 6B are partial sectional views of the important portion of the MONOS type memory cell taken along the lines A-A′ and B-B′ in FIG. 2 respectively;

FIGS. 7A, 7B are partial sectional views of the important portion of the MONOS type memory cell according to the first embodiment at a stage in the middle of its manufacturing process;

FIGS. 8A, 8B are partial sectional views of the important portion of the MONOS type memory cell at a stage subsequent to the stage shown in FIGS. 7A, 7B in the middle of the manufacturing process;

FIGS. 9A, 9B are partial sectional views of the important portion of the MONOS type memory cell at a stage subsequent to the stage shown in FIGS. 8A, 8B in the middle of the manufacturing process;

FIGS. 10A, 10B are partial sectional views of the important portion of the MONOS type memory cell at a stage subsequent to the stage shown in FIGS. 9A, 9B in the middle of the manufacturing process;

FIGS. 11A, 11B are partial sectional views of the important portion of the MONOS type memory cell at a stage subsequent to the stage shown in FIGS. 10A, 10B in the middle of the manufacturing process;

FIGS. 12A, 12B are partial sectional views of the important portion of the MONOS type memory cell at a stage subsequent to the stage shown in FIGS. 11A, 11B in the middle of the manufacturing process;

FIGS. 13A, 13B are partial sectional views of the important portion of the MONOS type memory cell at a stage subsequent to the stage shown in FIGS. 12A, 12B in the middle of the manufacturing process;

FIGS. 14A, 14B are partial sectional views of the important portion of the MONOS type memory cell at a stage subsequent to the stage shown in FIGS. 13A, 13B in the middle of the manufacturing process;

FIGS. 15A, 15B are partial sectional views of the important portion of the MONOS type memory cell at a stage subsequent to the stage shown in FIGS. 14A, 14B in the middle of the manufacturing process;

FIGS. 16A, 16B are partial sectional view of the important portion of the MONOS type memory cell at a stage subsequent to the stage shown in FIGS. 15A, 15B in the middle of the manufacturing process;

FIG. 17 is a plan view of an important portion of a MONOS type memory cell according to the second embodiment;

FIG. 18 is a view of a NOR type array constructed of MONOS type memory cells according to the second embodiment;

FIG. 19 is a partial sectional view of an important portion of a MONOS type memory cell according to the third embodiment, taken along the direction crossing its memory gate;

FIG. 20 is a partial sectional view of the important portion of the MONOS type memory cell according to the third embodiment at a stage in the middle of its manufacturing process;

FIG. 21 is a partial sectional view of the important portion at a stage subsequent to the stage shown in FIG. 20 in the middle of the manufacturing process;

FIG. 22 is a partial sectional view of the important portion at a stage subsequent to the stage shown in FIG. 21 in the middle of the manufacturing process;

FIG. 23 is a plan view of an important portion of a Fin structure MONOS type memory cell according to the fourth embodiment;

FIGS. 24A-24C are partial sectional views of the important portion of the Fin structure MONOS type memory cell taken along the lines A-A′, B-B′, and C-C′ in FIG. 23, respectively, and

FIG. 24D is a partial sectional view of the important portion of the Fin structure MONOS type memory cell taken along the line D-D′ in FIGS. 24A-24D;

FIGS. 25A-25C are partial sectional views of an important portion of a Fin structure MONOS type memory cell according to the fourth embodiment at a stage in the middle of its manufacturing process;

FIGS. 26A-26C are partial sectional views of the important portion of the MONOS type memory cell at a stage subsequent to the stage shown in FIGS. 25A-25C in the middle of the manufacturing process;

FIGS. 27A-27C are partial sectional views of the important portion of the MONOS type memory cell at a stage subsequent to the stage shown in FIGS. 26A-26C in the middle of the manufacturing process;

FIGS. 28A-28C are partial sectional views of the important portion of the MONOS type memory cell at a stage subsequent to the stage shown in FIGS. 27A-27C in the middle of the manufacturing process;

FIGS. 29A-29C are partial sectional views of the important portion of the MONOS type memory cell at a stage subsequent to the stage shown in FIGS. 28A-28C in the middle of the manufacturing process;

FIGS. 30A-30C are partial sectional views of the important portion of the MONOS type memory cell at a stage subsequent to the stage shown in FIGS. 29A-29C in the middle of the manufacturing process;

FIGS. 31A-31C are partial sectional view of the important portion of the MONOS type memory cell at a stage subsequent to the stage shown in FIGS. 30A-30C in the middle of the manufacturing process;

FIGS. 32A-32C are partial sectional views of the important portion of the MONOS type memory cell at a stage subsequent to the stage shown in FIGS. 31A-31C in the middle of the manufacturing process;

FIGS. 33A-33C are partial sectional views of the important portion of the MONOS type memory cell at a stage subsequent to the stage shown in FIGS. 32A-32C in the middle of the manufacturing process;

FIG. 34 is a plan view of an important portion of a Fin structure MONOS type memory cell according to the fifth embodiment;

FIG. 35 is a partial sectional view of an important portion of a Fin structure MONOS type memory cell according to the sixth embodiment;

FIG. 36 is a plan view of an important portion of a MONOS type memory cell that the inventors took into account; and

FIG. 37 is a partial sectional view of the important portion of the MONOS type memory cell taken along the line A-A′ in FIG. 36.

### DESCRIPTION OF PREFERRED EMBODIMENTS

The embodiment of the invention will be described in detail below in reference to the drawings. The embodiment is divided into two or more embodiments and explained in two or more sections as required for the sake of convenience. However, the embodiments are not irrelevant to each other except the case particularly so stated. That is, they are related to each other so that one is a modification of a part or all of another or offers the detail or supplementary explanation on it. Further, in the embodiments below, in the case where reference is made to the value in association with a component (including the number thereof, numerical value, quantity, range, and others), the component is not limited to the particular value except the following cases. The first is that the value is clearly specified. The second is that the component is limited to the particular value clearly in principle, etc. In such case, it is intended that a value above and below the particular value is also allowable. Still further, in regard to the embodiments below, it is obvious that their constituent elements (also, including elemental steps and others) are not necessarily essential except the following cases. The first is that they are clearly so noted. The second is that they can be considered to be essential clearly in principle. Likewise, in the embodiment below, in the case where reference is made to a constituent element in shape, locational relation, or the other item, the referred shape, locational relation, or other item substantially includes a shape, locational relation, or other item approximate or similar to the referred one except the following cases. The first is that it is clearly so noted. The second is that it can not be considered so clearly in principle. This also applies to the above cases of making references to a numerical value and a range.

In addition, in all the drawings to which reference is made for the description of the embodiments, like members are accompanied with the same reference character as a general rule, and the description thereof is omitted to avoid being repeated. Also, in the embodiments below, MIS FET (Metal Insulator Semiconductor Field Effect Transistor), which is a representative of field effect transistors, is abbreviated as MIS. Therefore, an n channel type MIS FET and a p channel type MIS FET are abbreviated as nMIS and PMIS respectively. In the case where the word “silicon nitride” is used, it indicates Si₃N₄ as a matter of course, but it includes not only Si₃N₄ but also an insulating film made of nitride of silicon that has a composition similar to that of Si₃N₄. Likewise, when the word “silicon oxide” is used, it indicates SiO₂ as a matter of course, but it includes not only SiO₂ but also an insulating film made of oxide of silicon that has a composition similar to that of SiO₂.

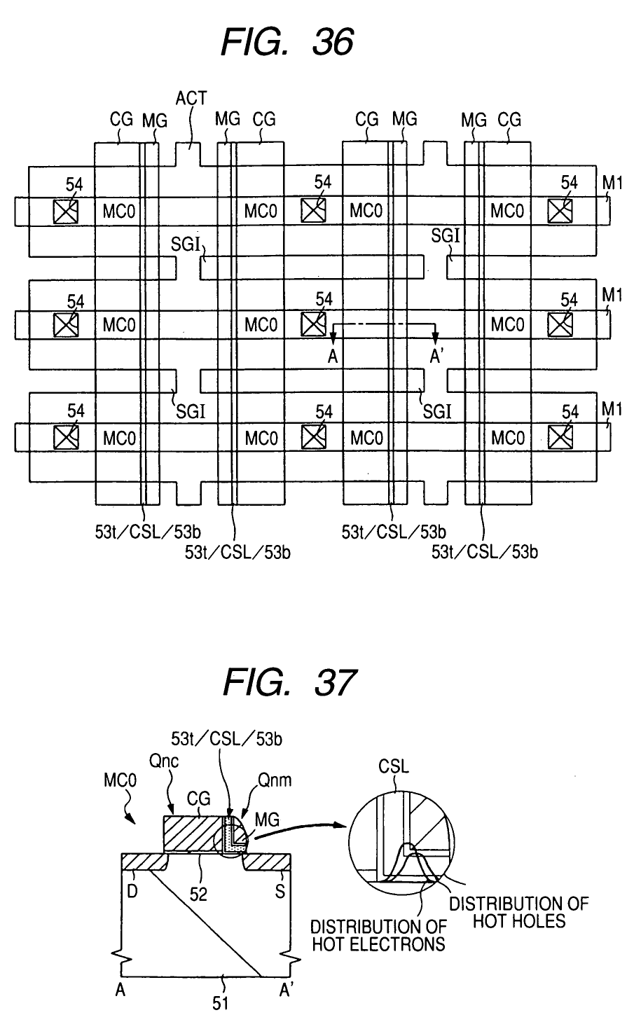

The inventors has made research and development concerning a MONOS type memory cell having a split-gate structure. FIGS. 36 and 37 show an example of such MONOS type memory cell that the inventors have already examined. Of the drawings, FIG. 36 is a plan view of an important portion of the MONOS type memory cell, and FIG. 37 is a partial sectional view of the important portion of the MONOS type memory cell taken along the line A-A′ in FIG. 36.

The MONOS type memory cell MC0 that the inventors have examined until now has an nMIS FET Qnc for selecting a memory cell (hereinafter abbreviated as selection-use nMIS, simply) and an nMIS FET Qnm for memory (herein after abbreviated as memory-use nMIS, simply), which are arranged to an active region ACT environed by an element-separating portion SGI on the main surface of its substrate 51 made of e.g. p type single-crystal silicon. A source S and a drain D of the memory cell MC are each composed of an n⁺ type diffusion region. On the main surface of the substrate 51 between the source S and the drain D, a control gate CG of the selection-use nMIS Qnc and a memory gate MG of the memory-use nMIS Qnm are placed adjoining each other. The control gate CG is placed through a gate-insulating film 52 on the main surface of the substrate 51. However, the memory gate MG is provided on one side face of the control gate CG. The insulation of the control gate CG from the memory gate MG is established by a multilayer film composed of an insulating film 53b, a charge storage layer CSL and an insulating film 53t, which are formed on the control gate side face in sequence from the undermost. Also, the memory gate MG is placed through the multilayer film on the main surface of the substrate 51. A first layer's conductor line M1 extending in the direction in which it crosses the memory gate MG is connected through a contact hole 54 to the drain D.

However, for the MONOS type memory cell MCO, generally adopted is a so-called local storage system, by which data is written by storing electrons in a part of the charge storage layer. In other words, electrons are generated from the side of the drain D adjacent to the control gate CG are accelerated by a strong electric field between the control gate CG and the memory gate MG to create hot electrons, and then the hot electrons are injected into the charge storage layer CSL thereby to write data. Further, according to local storage system, holes generated by tunneling between bands in a depletion layer on the side of the source S adjacent to the memory gate MG (at the end of the high-concentration diffusion layer) are accelerated by a strong electric field in the depletion layer to create hot holes. The hot holes are injected into the charge storage layer CSL, whereby data is erased. Therefore, it is possible to restrict a writing current by the control gate CG in writing data, while it becomes a problem in erasing data that a large current flows during the time of erasing data to increase the current consumption because there is no mechanism to restrict an erasing current. Also, it is also a problem that the spot into which hot electrons are injected in writing data doesn't agree with the spot into which hot holes are injected in erasing data and as such, it is required to create and inject a-large amount of hot holes in order to avoid leaving data after erasure, which reduces an erasing speed. Especially, in the case where the memory gate MG has a relatively long gate length, the difference in distribution between hot electrons and hot holes injected into the charge storage layer CSL becomes larger and as such, the erasing speed is reduced remarkably.

Further, when hot holes are injected in erasing data, a high voltage of e.g. about 7V is applied to the source S. On this account, a semiconductor chip on which a MONOS type memory cell is to be mounted needs a large current capacity voltage-boosting power source attached thereto, and thus the area of its power source unit (e.g. charge-pumping circuit) is made larger. This makes difficult the application of a MONOS type memory cell to a semiconductor device limited in its power source capacity, e.g. a non-contact type IC card.

### First Embodiment

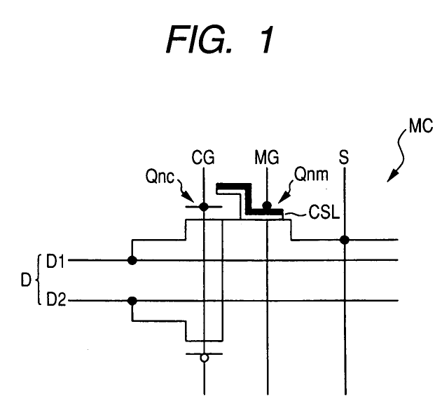

The circuit diagram of a MONOS type memory cell according to the first embodiment is shown in FIG. 1.

The memory cell MC has two transistors, e.g. selection-use nMIS (first field effect transistor) Qnc and memory-use nMIS (second field effect transistor) Qnm between a drain D and a source S. The drain D is composed of a first drain (first diffusion region) D1 and a second drain (second diffusion region) D2. The first drain D1 shows n type conductivity, whereas the second drain D2 shows p type conductivity. In addition, the source (third diffusion region) S shows n type conductivity. The selection-use nMIS Qnc has a control gate (first gate) CG, whereas the memory-use nMIS Qnm has a memory gate (second gate) MG and a charge storage layer CSL.

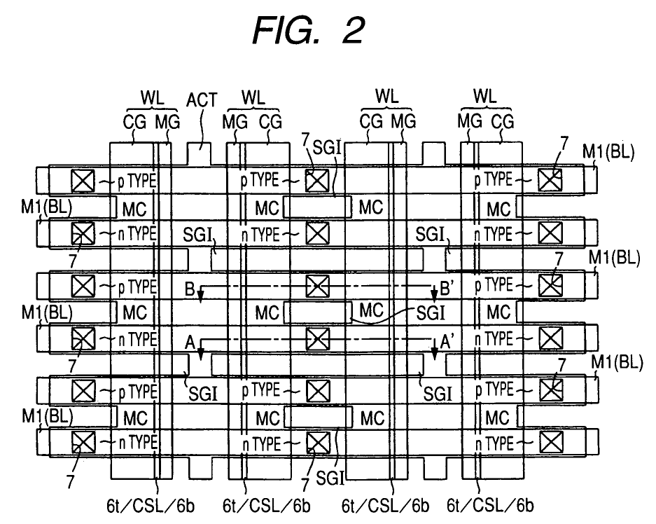

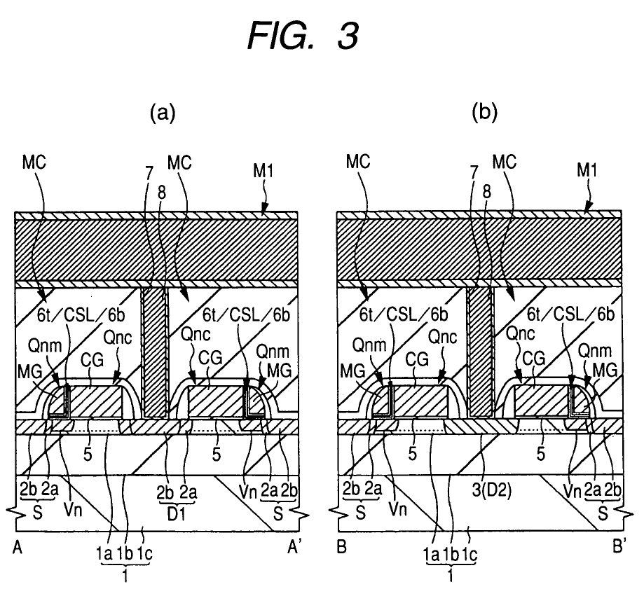

FIG. 2 is a plan view showing an important portion of a MONOS type memory cell according to the first embodiment. FIGS. 3A and 3B are partial sectional views respectively taken along the lines A-A′ and B-B′ in FIG. 2, showing the important portion of the MONOS type memory cell. The memory cell shown in the drawings is of memory gate stacked type of side-wall scheme.

The substrate 1 is an SOI (Silicon On Isolator) substrate including a semiconductor substrate. The shape of the substrate may be not only a disk or substantially disk form but also the forms of square, rectangle, etc. The SOI substrate has the structure in which an isolator 1b is formed on a supporting substrate 1c, and a silicon layer 1a of p type single-crystal silicon is formed on the isolator. In an active region ACT of the main surface (i.e. a face to form a device on) of the substrate 1, a selection-use nMIS Qnc and a memory-use nMIS Qnm of a memory cell MC are placed. The first drain D1 and source S of the memory cell MC each have, for example, an n⁻ type diffusion region 2a and an n⁺ type diffusion region 2b with an impurity concentration higher than that of the diffusion region 2a (LDD (Lightly Doped Drain) structure). The n⁻ type diffusion region 2a is located closer to a channel of the memory cell MC, and the n⁺ type diffusion region 2b is located in the place spaced away from the channel of the memory cell MC by the distance that the n⁻ type diffusion region 2a occupies. The second drain D2 of the memory cell MC has, for example, a p⁺ type diffusion region 3. The first drain D1 and second drain D2 are arranged in the direction along which a memory gate MG runs. The first and second drains D1, D2 are electrically separated from each other by an element-separating portion SGI, and formed in different planar locations in the main surface of the substrate 1. The impurity concentration of the silicon layer la is e.g. about 10¹⁶/cm⁻³, and the impurity concentrations of the n⁺ type diffusion region 2b and p⁺ type diffusion region 3 are, e.g. about 10²⁰/cm⁻³.

On the main surface of the substrate 1, a control gate CG of the selection-use nMIS Qnc and a memory gate MG of the memory-use nMIS Qnm, which are next to each other, run between the first and second drains D1, D2 and the source S. Along the direction in which the control gate CG and memory gate MG extend, a number of memory cells MC are formed adjoining one another through element-separating portions SGI formed on the substrate 1. The control gate CG and memory gate MG are made of e.g. n type, low-resistant polycrystalline silicon. The gate length of the control gate CG is e.g. about 0.2 μm, and that of the memory gate MG is e.g. about 0.1 μm.

Between the control gate CG and silicon layer 1a is provided a gate-insulating film (first insulating film) 5 which is composed of a thin silicon oxide having a thickness of e.g. 2 to 3 nm approximately. Therefore, the control gate CG is placed on the element-separating portion SGI and the gate-insulating film 5 on the silicon layer 1a. In the silicon layer la underlying the gate-insulating film 5, a p type semiconductor region is formed to adjust the threshold voltage of the selection-use nMIS Qnc. To the semiconductor region, e.g. boron is introduced.

The memory gate MG is provided along a side wall of the control gate CG. The memory gate MG is insulated from the control gate CG by a multilayer film (i.e. second insulating film, which is denoted by the character string “6t/CSL/6b” in the drawings). The multilayer film is provided on the surface of the control gate CG and composed of an insulating film 6b, a charge storage layer CSL, and an insulating film 6t in sequence from the undermost. Also, the memory gate MG is located above the silicon layer 1a through the insulating films 6b, 6t and the charge storage layer CSL. In the main surface of the substrate 1 underlying the insulating film 6b, an n type semiconductor region Vn is formed to adjust the threshold voltage of the memory-use nMIS Qnm. Into the semiconductor region Vn, for example, arsenic or phosphorus is introduced.

The charge storage layer CSL is provided so as to be sandwiched between the insulating films 6t, 6b lying above and below it. The charge storage layer is made of e.g. silicon nitride, whose thickness is less than or equal to 50 nm, for example. The insulating films 6b, 6t are made of e.g. silicon oxide and the like. The thickness of the insulating film 6b is e.g. 4 to 5 nm, approximately. That of the insulating film 6t is e.g. about 6 nm. The insulating film 6t may be formed with silicon nitride (SiON). Also, the insulating films 6b, 6t may be formed as silicon oxide films, each containing nitrogen.

The first drain D1 and second drain D2 are each connected with the first layer's conductor line M1 (first or second conductor line) through the plug 8 embedded in the contact hole 7. In a memory cell array with memory cells arrayed in e.g. a two-dimensional lattice, the conductor line M1 serves as a bit line BL, which is one of signal lines extending in X and Y directions. The memory gate MG and control gate CG each serve as a word line WL, which is e.g. one of the signal lines and runs in a direction orthogonal to the bit line BL.

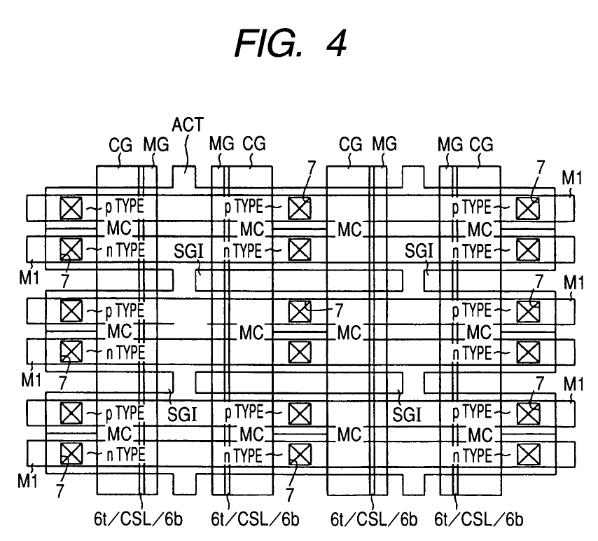

The first drain D1 and second drain D2 are electrically separated from each other by the element-separating portion SGI in the memory cells MC shown in FIGS. 3A, 3B. However, the first drain D1 and second drain D2 may be formed so as to adjoin each other without the element-separating portion SGI as shown in FIG. 4, for example. In this case, the conductor lines M1 may be connected to the first drain D1 and second drain D2 respectively.

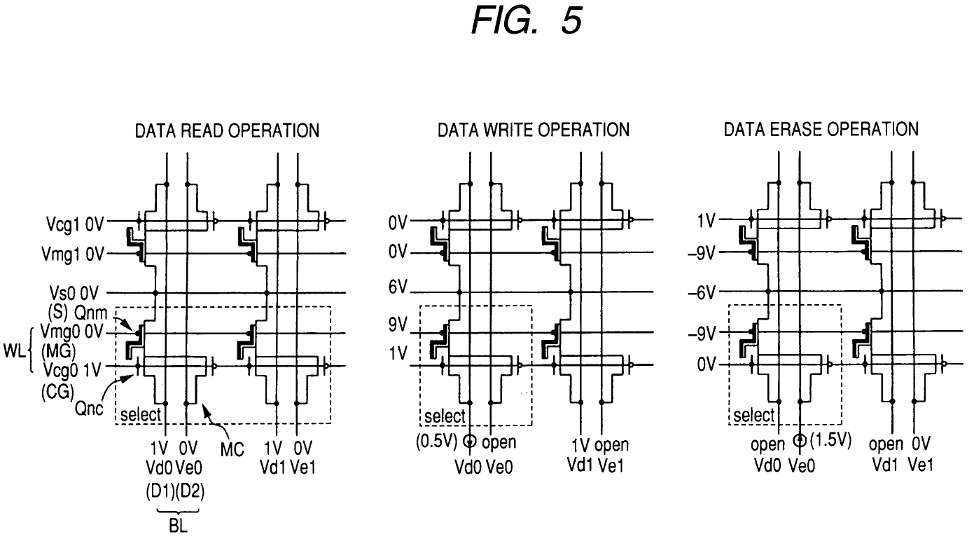

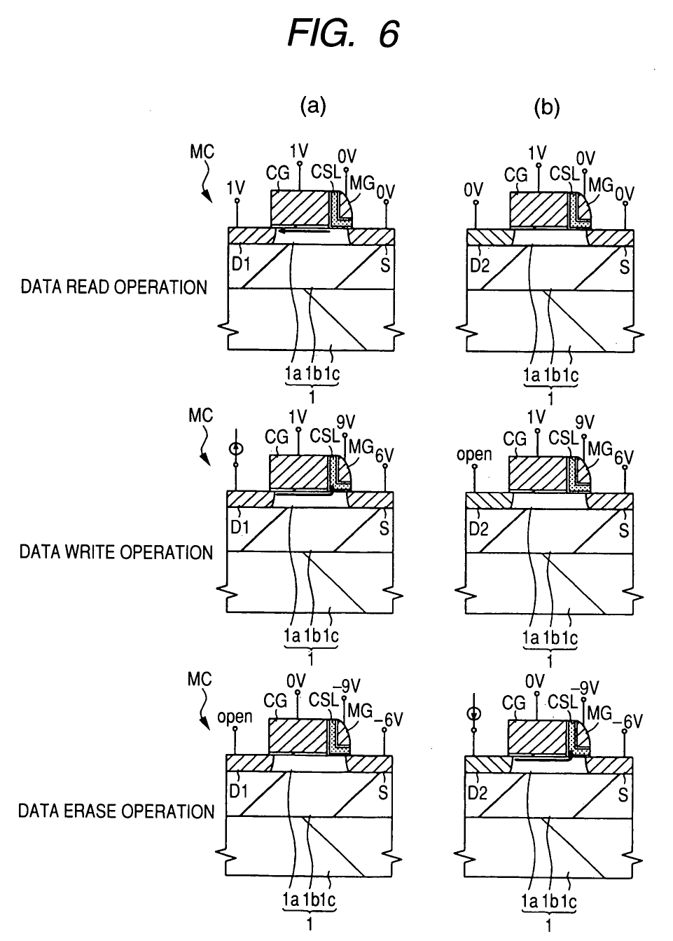

Now, an example of each of the operations of the MONOS type memory cell according to the first embodiment will be described in reference to FIGS. 5, 6A and 6B. FIG. 5 shows an example of each of the data read operation, data write operation, and data erase operation of a selected memory cell (which is surrounded by a dotted line) in a NOR type array constructed of MONOS type memory cells according to the first embodiment. FIGS. 6A, 6B are partial sectional views of the important portion of the MONOS type memory cell according to the first embodiment, taken along the same directions as the directions which FIGS. 3A, 3B are taken along. FIGS. 6A, 6B are views of assistance in showing an example of each of the data read operation, data write operation, and data erase operation of the selected memory cell as is FIG. 5.

In the data read operation, the selection-use nMIS Qnc of the memory cell MC is turned on by applying a voltage of e.g. about 1V to the control gate CG and first drain D1 of the selected memory cell MC, and a voltage of e.g. 0V (zero volt) to the memory gate MG, second drain D2, and source S. During the operation, the threshold voltage of the memory-use nMIS Qnm is changed depending on the presence or absence of electrons in the charge storage layer CSL, according to which the current flow between the first drain D1 and source S is caused or stopped. In this way, data is to be read. Incidentally, the second drain D2 is fixed at a potential of zero (0) and as such, there is no possibility of a leakage current flowing through the second drain D2.

In the data write operation, an electronic current is caused to flow through the first drain D1 by applying a voltage of e.g. about 1V to the control gate CG of the selected memory cell MC, a voltage of e.g. about 9V to the memory gate MG, and a voltage of e.g. about 6V to the source S. During the operation, the second drain D2 is kept in open state (its released state) thereby avoiding a current flowing through the second drain D2. Thus, electrons are injected through the first drain D1 of the memory cell MC to create hot electrons under a strong electric field between the control gate CG and the memory gate MG. The hot electrons are injected into the charge storage layer CSL located in the vicinity of and underlying the memory gate MG, whereby data is written.

Further, in the data erase operation, a hole current is caused to flow through the second drain D2 by applying a voltage of e.g. 0V (zero volt) to the control gate CG of the selected memory cell MC, a voltage of e.g. about −9V to the memory gate MG, and a voltage of e.g. about −6V to the source S. During the operation, the first drain D1 is kept in its released state, thereby avoiding a current flowing through the first drain D1. Thus, holes are injected through the second drain D2 of the memory cell MC to create hot holes under a strong electric field between the control gate CG and the memory gate MG. The hot holes are injected into the charge storage layer CSL located in the vicinity of and underlying the memory gate MG, whereby data is erased.

During the operation, a negative voltage is applied to the source S. However, an SOI substrate is used as the substrate 1 and as such, the electronic current never flows into the substrate 1. In addition, because the negative voltage applied to the memory gate MG is larger than that applied to the source S in absolute value, no electronic current flows through the channel underlying the memory gate MG.

In this way, the hot electrons to be injected into the charge storage layer CSL in writing data and the hot holes to be injected into the charge storage layer CSL in erasing data are injected into almost the same region. As a result, the difference in distribution between the hot electrons and hot holes owing to their injections is small, which makes it possible to avoid leaving data after erasure. In addition, it is not required to inject a large amount of hot holes and as such, it is also possible to avoid the problem of the erasing speed slowing. Further, even when data is erased, it is possible to restrict the current consumption with the control gate CG as in the case of writing data, and therefore the current consumption can be reduced.

Still further, the holes are efficiently accelerated by the strong electric field between the control gate CG and the memory gate MG like the electrons in writing data and as such, less capacity is required for the voltage-boosting power source. In addition, since it is not needed to generate the positive and negative high voltages simultaneously, the area of the power source unit may be reduced, thereby enabling e.g. the application to non-contact type IC cards.

In the first embodiment, it is also possible to form the silicon layer 1a underlying the control gate CG so as to have a concentration which makes the layer la totally depleted. In this case, making the layer la totally depleted widely decreases the amount of depletion charge and accordingly increases the charge, which contributes to a drain current. As a result, a steep subthreshold characteristic can be obtained. This makes it possible to secure a drain current even with a low voltage, and therefore it becomes possible to produce a semiconductor device reduced in power consumption.

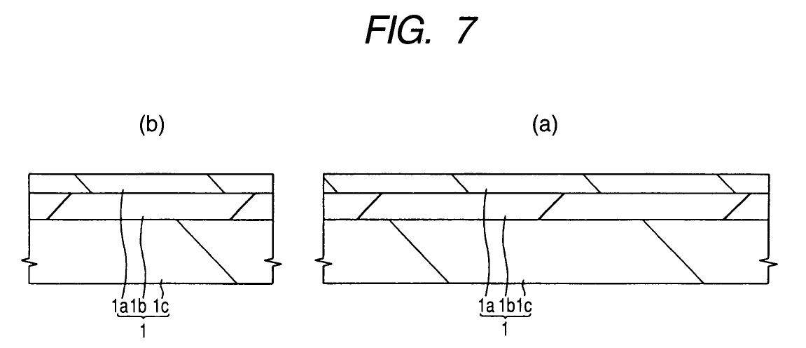

Now, a method of manufacturing a MONOS type nonvolatile memory cell according to the first embodiment will be described in reference to FIGS. 7A, 7B to 16A, 16B in the order in which the steps thereof are carried out of the drawings, the drawings having a drawing number accompanied with the character “A” at the end show substantially the same portion as the important portion shown in the partial sectional view of FIG. 3A. Likewise, the drawings having a drawing number with accompanied with the character “B” at the end show substantially the same portion as the important portion shown in the partial sectional view of FIG. 3B. Also, the drawings having a drawing number accompanied with the character “A” at the end show, in section, an important portion of an nMIS constituting a peripheral circuit.

First, the substrate 1 is prepared, as shown in FIGS. 7A, 7B. The substrate 1 is an SOI substrate, which is composed of: a supporting substrate 1c made of single-crystal silicon; a silicon layer 1a made of a p type single-crystal silicon having a specific resistance of e.g. 1 to 10 Ωcm approximately; and an isolator 1b provided between the supporting substrate 1c and the silicon layer 1a. The thickness of the silicon layer 1a is, for example, about 0.2 μm.

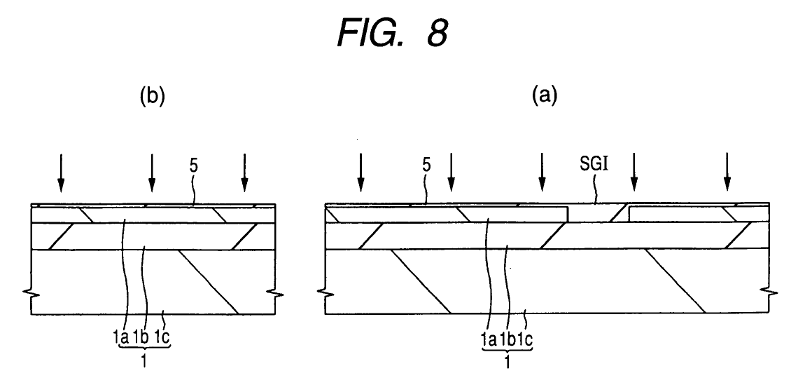

Next, as shown in FIGS. 8A, 8B, the following are formed in the main surface of the substrate 1, for example: a groove-shaped element-separating portion SGI; and an active region arranged so as to be surrounded by the element-separating portion. More specifically, a separating groove is formed in place in the silicon layer 1a that the substrate 1 includes, followed by depositing an insulating film of e.g. silicon oxide on the silicon layer 1a. Then, the insulating film is polished by CMP (Chemical Mechanical Polishing) method or the like so that the insulating film is left only inside the separating groove, thereby forming the element-separating portion SGI.

Subsequently, e.g. boron fluoride is introduced into the silicon layer la by ion implantation. Thus, a p type semiconductor region to form a channel of a selection-use nMIS Qnc is formed in the silicon layer 1a. Also, the p type semiconductor region for the channel formation may be formed so as to have a concentration that makes the semiconductor region totally depleted. In the case of so forming the p type semiconductor region, it is possible to make a semiconductor device reduced in power consumption as described above. Subsequently, the substrate 1 is subjected to an oxidizing treatment, thereby forming, on the silicon layer 1a, a gate-insulating film 5 of e.g. silicon oxide having a thickness of 2 to 3 nm approximately.

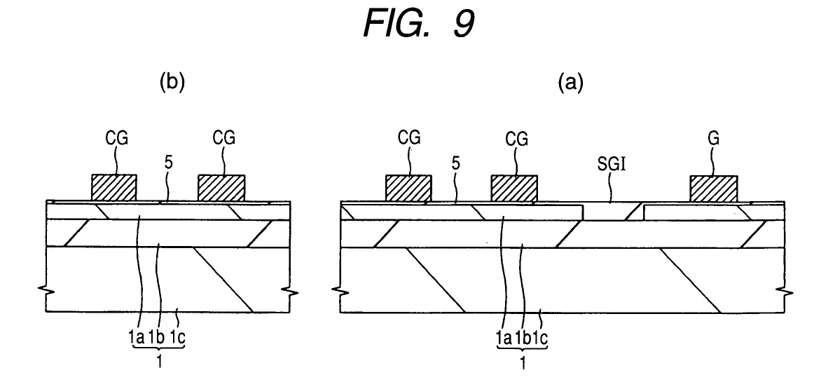

Next, as shown in FIGS. 9A, 9B, a conductor film of polycrystalline silicon of low resistance is deposited on the gate-insulating film 5 up to a thickness of about 200 nm by CVD (Chemical Vapor Deposition), followed by patterning the conductor film through the lithography and etching techniques. As a result, the control gate CG and the gate G of the nMIS constituting a peripheral circuit are formed.

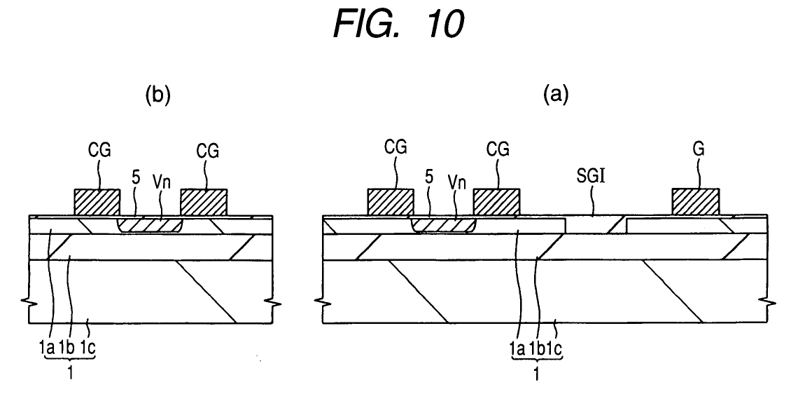

Next, as shown in FIGS. 10A, 10B, using the control gate CG and the resist pattern formed by a lithography technique as a mask, e.g. arsenic or phosphorus is doped into the silicon layer 1a by ion implantation thereby to form an n type semiconductor region Vn to form a channel of a memory-use nMIS Qnm.

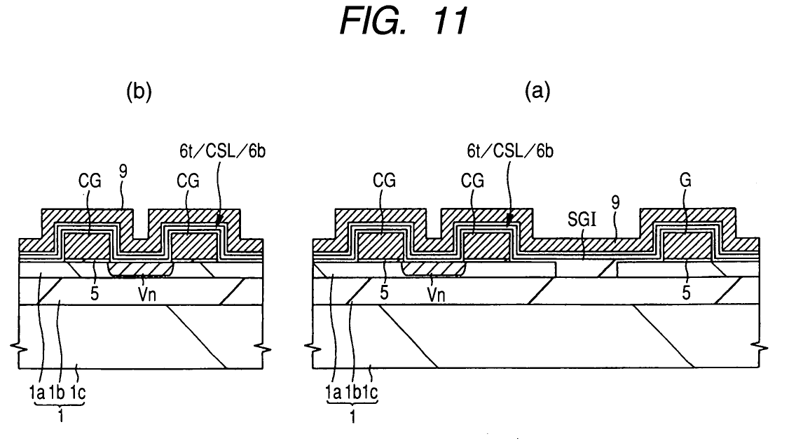

Then, as shown in FIGS. 11A, 11B, on the main surface of the substrate 1 are formed an insulating film 6b of e.g. silicon oxide, a charge storage layer CSL of silicon nitride, and an insulating film 6t of silicon oxide in sequence. After that, a conductor film 9 of polycrystalline silicon of low resistance, which is intended to form a memory gate, is further deposited thereon. The insulating film 6b is formed by e.g. thermal oxidation, and the thickness thereof is about 6 nm, for instance. The charge storage layer CSL is formed by e.g. CVD method, which is e.g. about 12 nm in thickness. The insulating film 6t is formed by e.g. CVD method, and the thickness thereof is e.g. about 5 nm. The conductor film 9 is formed by e.g. CVD method, and the thickness thereof is e.g. 150 nm approximately.

Subsequently, as shown in FIGS. 12A, 12B, the conductor film 9 is etched by anisotropic dry etching, whereby side walls 9a of the conductor film 9 are formed on sides of the control gate CG. Subsequently, a resist pattern 10 to form a memory gate is formed on the main surface of the substrate 1 by the lithography technique. Thereafter, the resist pattern 10 is used as a mask to etch the side walls 9a exposed from the mask, whereby a memory gate MG (side wall 9a) is formed on one side of the control gate CG. After that, the resist pattern 10 is removed, followed by selectively etching the insulating films 6b, 6t and the charge storage layer CSL.

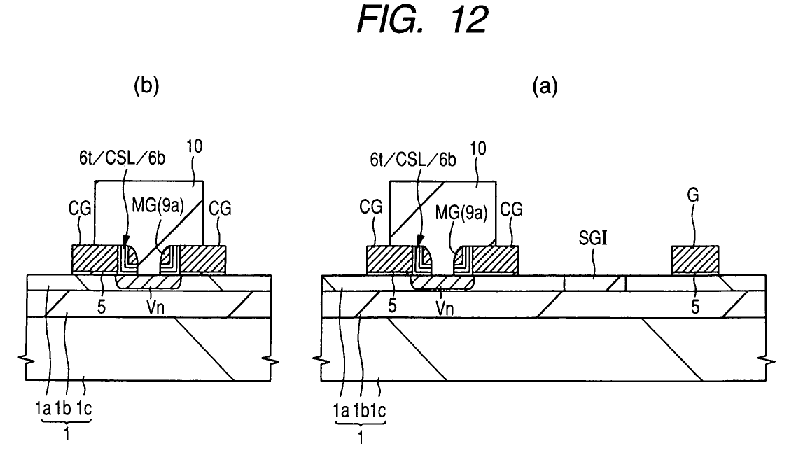

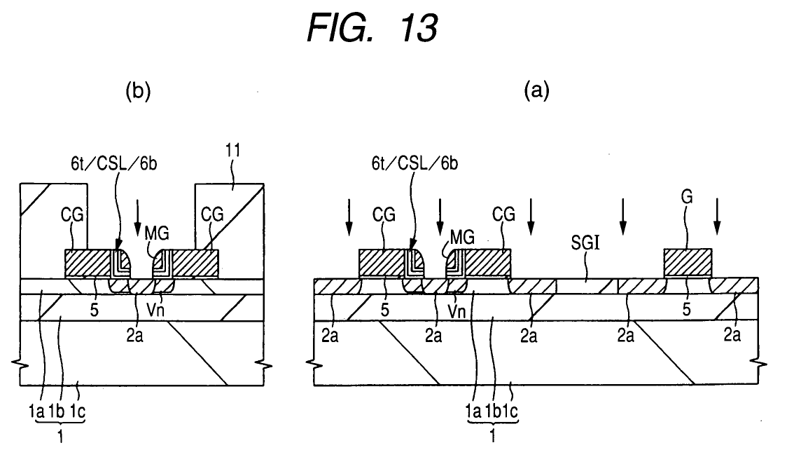

Next, as shown in FIGS. 13A, 13B, a resist pattern 11 for covering a second drain-forming region is formed by the lithography technique. After that, using a set of the control gate CG, the memory gate MG, the gate G of the nMIS constituting a peripheral circuit and the resist pattern 11 as a mask, e.g. arsenic or phosphorus is doped into the silicon layer la by ion implantation, whereby n⁻ type diffusion regions 2a are formed in the silicon layer 1a so as to self-match with respect to the control gate CG, the memory gate MG, and the gate G of the nMIS constituting a peripheral circuit.

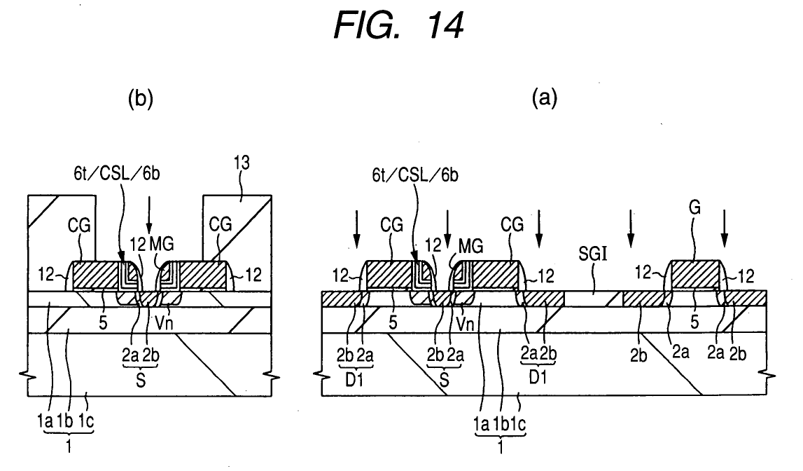

Subsequently, as shown in FIGS. 14A, 14B, the resist pattern 11 is removed, and then an insulating film of e.g. silicon oxide is deposited on the main surface of the substrate 1 up to a thickness of about 100 nm by the CVD method. Thereafter, the insulating film is subjected to anisotropic dry etching. As a result, side walls 12 are formed on the other side of the control gate CG, on the memory gate MG, and on both the sides of the gate G of the nMIS constituting a peripheral circuit.

Next, a resist pattern 13 for covering the second drain-forming region is formed by the lithography technique. After that, using a set of the control gate CG, the memory gate MG, the gate G of the nMIS constituting a peripheral circuit, and the resist pattern 13 as a mask, e.g. arsenic or phosphorus is doped into the silicon layer 1a by ion implantation, whereby n⁺ type diffusion regions 2b are formed in the silicon layer la so as to self-match with respect to the control gate CG, the memory gate MG, and the gate G of the nMIS constituting a peripheral circuit. Thus, the first drain D1 and source of the memory cell MC, and the drain and source of the nMIS constituting a peripheral circuit, each composed of the n type diffusion region 2a and n⁺ type diffusion region 2b, are formed.

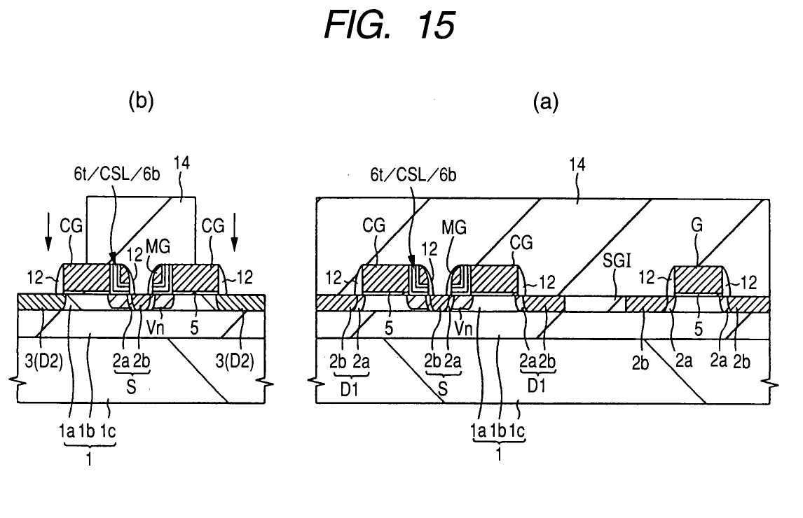

Next, as shown in FIGS. 15A, 15B, after the resist pattern 13 is removed, a resist pattern 14 for covering the first drain-forming region and source-forming region is formed by the lithography technique. After that, using a set of the control gate CG and the resist pattern 14 as a mask, e.g. boron or boron fluoride is doped into the silicon layer la by ion implantation, whereby a p⁺ type diffusion region 3 is formed in the silicon layer 1a so as to self-match with respect to the control gate CG. Thus, the second drain D2 of the memory cell MC composed of the p⁺ type diffusion region 3 is formed.

In this way, the drain D composed of the two kinds of drains, i.e. first and second drains D1 and D2, and the source S are formed, and the selection-use nMIS Qnc and memory-use nMIS Qnm are formed, whereby a MONOS type memory cell is manufactured. In addition, an nMIS constituting a peripheral circuit and a pMIS are manufactured, but the description on the manufacturing method of the PMIS is omitted here.

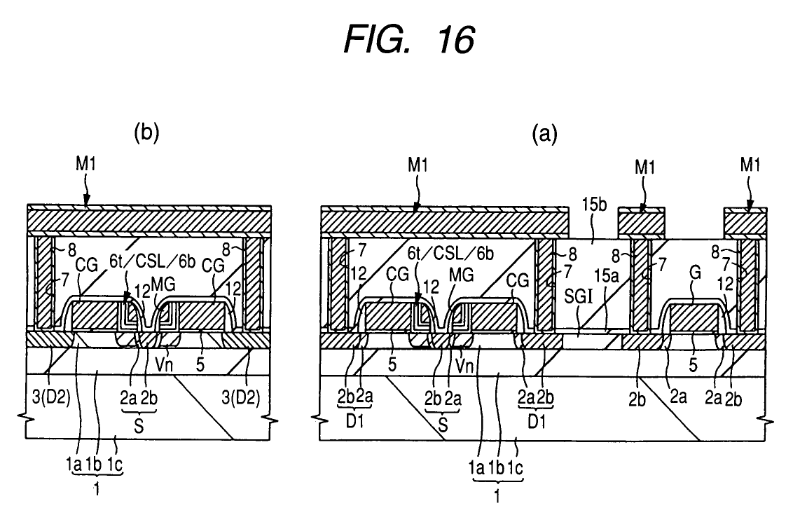

Next, as shown in FIGS. 16A, 16B, after insulating films of e.g. silicon nitride 15a and silicon oxide 15b are deposited on the main surface of the substrate 1 by CVD method, contact holes 7 are formed in the insulating films by lithography and dry etching techniques. Subsequently, inside each contact hole 7 is formed a plug 8. The plug 8 has: a relatively thin barrier film, which is composed of a multilayer film of e.g. titanium and titanium nitride; and a relatively thick conductor film made of tungsten, aluminum, or the like, which is formed so as to be wrapped by the barrier film. After that, the first layer's conductor line M1 of e.g. tungsten or aluminum is formed on the silicon oxide film 15b, whereby the memory cell MC as shown in FIGS. 3A, 3B is substantially finished. Now, the plugs 8 don't have to be formed, and the first layer's conductor line M1 may be formed also inside the contact hole 7 instead.

After the steps described above, a usual manufacturing process for semiconductor devices is carried out, thereby manufacturing a MONOS type nonvolatile memory cell.

### Second Embodiment

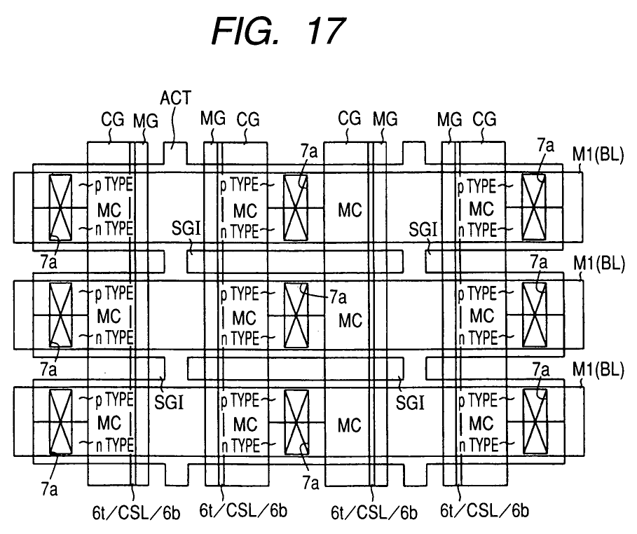

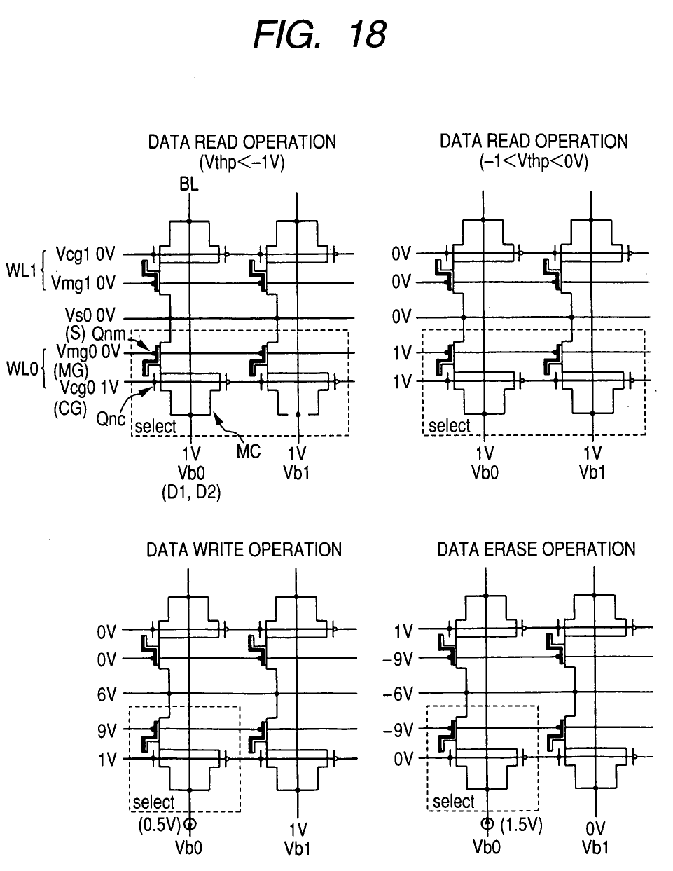

A MONOS type memory cell according to the second embodiment, which has a bit line connected to its first and second drains and shared, will be described in reference to FIGS. 17 and 18. Of the drawings, FIG. 17 is a plan view of an important portion of the MONOS type memory cell according to the second embodiment. FIG. 18 shows an example of each of the data read operation, data write operation, and data erase operation of a selected memory cell (which is surrounded by a dotted line) in a NOR type array constructed of MONOS type memory cells according to the second embodiment.

For example, the memory cell according to the second embodiment has: a first drain D1 and a second drain D2 adjacent to each other formed in different planar locations in the main surface of the substrate 1; a contact hole 7a formed athwart both the first drain D1 and second drain D2; and a first layer s conductor line M1 (third conductor line) electrically connected to the first drain D1 and second drain D2 through the contact hole 7a as shown in FIG. 17, in which the element-separating portion SGI between the first drain D1 and second drain D2 is not formed as shown in FIGS. 3A, 3B in association with the first embodiment. Alternatively, a silicide layer of e.g. cobalt silicide may be formed on a surface of an n type diffusion region constituting the first drain D1 (which corresponds to the n⁺ type diffusion region 2b shown in FIG. 3A in association with the first embodiment) and a surface of a p type diffusion region constituting the second drain D2 (which corresponds to the p⁺ type diffusion region 3 shown in FIG. 3B in association with the first embodiment) to electrically connect the first drain D1 with the second drain D2, followed by electrically connecting the first layer's conductor line M1 to the silicide layer. Thus, a bit line BL composed of the conductor line M1, which is shared because it is connected to both the first and second drains D1 and D2 of the memory cell MC, is formed. In this case, if the threshold voltages of the selection-use nMIS Qnc and memory-use nMIS Qnm are appropriate, making the bit line BL sharable can reduce the pitch width between bit lines BL and as such, the width of the memory cell MC can be reduced in one direction.

That is, in the first embodiment an element-separating portion SGI is formed between the first drain D1 and second drain D2 of the memory cell MC, whereas in the second embodiment is no element-separating portion SGI in a drain-forming region of the memory cell MC. This allows the length of the memory cell to be shortened in the direction of its gate width.

For example, the control gate CG sets the threshold voltage Vthn when taken into account from the viewpoint of an nMIS within a range of 0 to 0.5V, and it sets the threshold voltage Vthp when taken into account from the viewpoint of a PMIS within a range of −1 to −1.5V.

In the data read operation, e.g. 1V (Vb0, Vb1) to the bit lines BL, e.g. 1V (Vcg0) to the control gate CG of the selected word line WL0, and e.g. 0 (zero) volt (Vcg1) to the control gate CG of the non-selected word line WL1 are applied respectively. Then, the control gate CG of the selected word line WL0 is brought into conduction, while the control gate CG of the non-selected word line WL1 is out of conduction because its threshold voltage Vthp is lower than −1V. As a result, it becomes possible to read out the state of the memory gate MG of the selected word line WL0.

Incidentally, even when the threshold voltage Vthp when taken into account from the viewpoint of a pMIS is −1 to 0V, selecting the word line WL with a voltage applied to the memory gate MG enables the data read operation. For instance, the operation may be carried out by setting the threshold voltage Vthe of the memory gate MG in its erase state at e.g. 0 to 1V, and the threshold voltage Vthw in its write state e.g. above 1V, and then applying e.g. 1V (Vmg0) to the memory gate MG of the selected word line WL0 and e.g. 0V to the memory gate MG of the non-selected word line WL1.

In the data write operation, e.g. 1V (Vcg0) to the control gate CG of the selected word line WL0, and e.g. 0V (Vcg1) to the control gate CG of the non-selected word line WL1 are applied respectively. Then, when a current of e.g. 1 μA required for writing is caused to flow into the first drain D1 from a current source, the potential Vb0 of the selected bit line BL is raised by about 0.5V and then electrons are injected from the first drain D1, whereby data is written into the memory cell. At this time, since the threshold voltage Vthn of the control gate CG of the non-selected word line WL1 (nMIS) is larger than the value, Vcg1-Vb0, electrons are not injected and therefore no data is written in the corresponding memory cell.

In the data erase operation, e.g. 0V (Vcg0) to the control gate CG of the selected word line WL0, and e.g. 1V (Vcg1) to the control gate CG of the non-selected word line WL1 are applied respectively. Then, when a current of e.g. 1 μA required for erasing data is caused to flow into the second drain D2 from the current source, the potential Vb0 of the selected bit line BL is raised by about 1.5V, and the threshold voltage Vthp of the control gate CG of the selected word line WL0 (pMIS) becomes larger than the value, Vcg0-Vb0. As a result, holes are injected from the second drain D2, whereby data is erased. At this time, since the threshold voltage Vthp of the control gate CG of the non-selected word line WL1 (pMIS) is lower than the value, Vcg1-Vb0, holes are not injected and therefore no data is erased in the corresponding memory cell.

### Third Embodiment

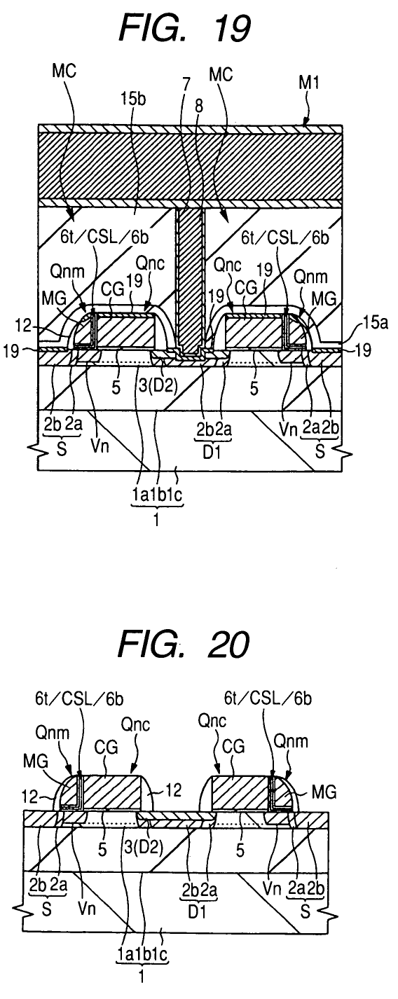

A MONOS type memory cell according to the third embodiment, which has a bit line connected to first and second drains thereof and shared, will be described in reference to FIG. 19. FIG. 19 is a partial sectional view of an important portion of the MONOS type memory cell according to the third embodiment, which is taken along the direction crossing its memory gate at right angles.

In the second embodiment the first and second drains D1 and D2 in contact with each other are formed in different planar locations in the main surface of the substrate 1, whereas in the MONOS type memory cell according to the third embodiment the first and second drains D1 and D2 are formed in contact with each other in the depth direction of the substrate 1. This enables not only the reduction in the areas of the n⁺ type diffusion region 2b constituting the first drain D1 and the p⁺ type diffusion region 3 constituting the second drain D2, but also more reliable data erasure because of the agreement between the electrons' flow path during the time of writing data and the holes' flow path during the time of erasing data.

That is, the second embodiment needs the area for forming two drains, i.e. first and second drains D1 and D2 of the memory cell MC, whereas in the third embodiment the first drain D1 is formed at a place below the second drain D2 so that the first and second drains D1 and D2 coincide in location with each other in two dimensions. This makes it possible to reduce the length of the memory cell MC in the direction of its gate width.

A method of manufacturing the MONOS type nonvolatile memory cell according to the third embodiment will be described in reference to FIGS. 20 to 22 in the order in which the steps thereof are carried out. The manufacturing method in association with the third embodiment is the same as the method of manufacturing the MONOS type memory cell according to the first embodiment in that it includes the steps of forming a control gate CG, then forming a charge storage layer CSL and a memory gate MG on one side of the control gate CG, and subsequently forming an n⁺ type diffusion region 2b, namely the steps shown in reference to FIGS. 7A, 7B to 14A, 14B. Therefore, the descriptions about those steps are to be omitted and only the later steps will be described here.

Subsequently to the step shown in reference to FIGS. 14A, 14B, the resist pattern 13 is removed, and then a resist pattern for covering the source-forming region is formed by the lithography technique, as shown in FIG. 20. After that, using a set of the control gate CG and the resist pattern as a mask, e.g. boron or boron fluoride is doped into an upper portion of the n⁺ type diffusion region 2b formed in the silicon layer la up to a relatively shallow depth by ion implantation. As a result, a surface region of the n⁺ type diffusion region 2b formed in the preceding step is inverted to p⁺ type in its conductivity type to form a p⁺ type diffusion region 3 so that it self-matches with respect to the control gate CG. Thus, a drain D of two-layer structure is formed. The drain D consists of: a second drain D2 composed of the p⁺ type diffusion region 3 as its upper layer; and a first drain D1 composed of the n⁺ diffusion region 2b as its lower layer. The thicknesses of the p⁺ type diffusion region 3 and n⁺ type diffusion region 2b are, for example, about 0.1 μm respectively.

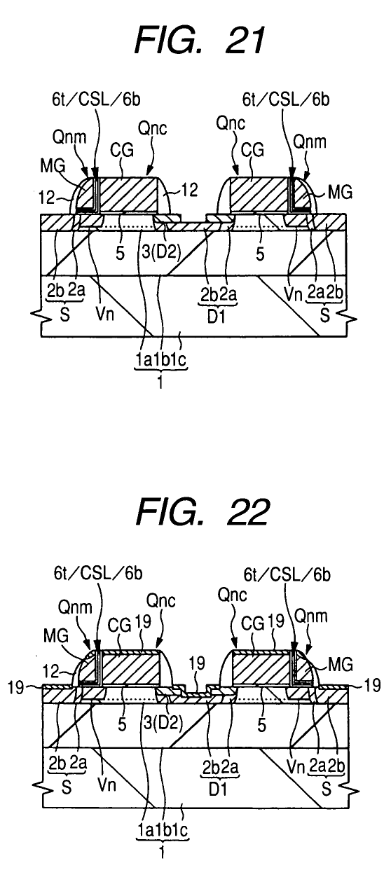

Next, as shown in FIG. 21, the p⁺ type diffusion region 3 is partially removed by the lithography and dry etching techniques thereby to expose the n⁺ type diffusion region 2b.

Then, as shown in FIG. 22, e.g. a silicide layer 19 of cobalt silicide is formed, by a salicide process technique, on exposed surfaces of the n⁺ type diffusion region 2b and the p⁺ type diffusion region 3, which the drain D (D1, D2) includes, and on an exposed surface of the n⁺ type diffusion region 2b, which the source S includes. Thus, the n⁺ type diffusion region 2b and the p⁺ type diffusion region 3, which the drain D (D1, D2) includes, are electrically connected through the silicide layer 19. In this step, the silicide layer 19 is also formed on the surfaces of the control gate CG and memory gate MG where polycrystalline silicon is exposed.

Subsequently, insulating films composed of e.g. silicon nitride film 15a and a silicon oxide film 15b are deposited on the main surface of the substrate 1 by CVD method. After that, a contact hole 7 through the insulating films is formed by the lithography and dry etching techniques. Then, a plug 8 is formed inside the contact hole 7. Thereafter, on the silicon oxide film 15b is formed a first layer's conductor line M1 of e.g. tungsten or aluminum, whereby a memory cell MC as shown in FIG. 19 is substantially finished.

In the third embodiment, the drain D of two-layer structure having a p⁺ type diffusion region 3 as its upper layer and an n⁺ type diffusion region 2b as its lower layer is formed. However, a drain D of two-layer structure having an n⁺ type layer diffusion region 2b as its upper layer, and a p⁺ type diffusion region 3 as its lower layer may be formed instead.

### Fourth Embodiment

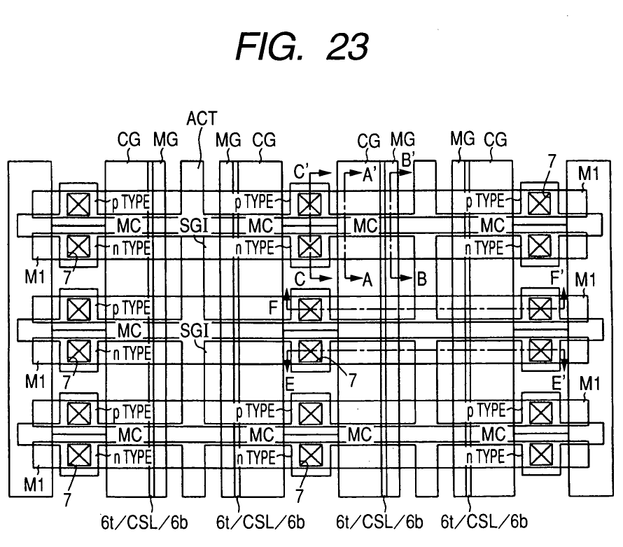

A MONOS type memory cell formed in a Fin structure SOI according to the fourth embodiment will be described in reference to FIGS. 23 and 24A-24D. FIG. 23 is a plan view of an important portion of the MONOS type memory cell of Fin structure according to the fourth embodiment. FIGS. 24A-24C are partial sectional views of the important portion of the MONOS type memory cell of Fin structure taken along the lines A-A′, B-B′, and C-C′ in FIG. 23 respectively. FIG. 24D is a partial sectional view of the important portion of the MONOS type memory cell of Fin structure, taken along the line D-D′ in FIGS. 24A-24C.

In the fourth embodiment, an SOI substrate is used as the substrate 1 as in the case of the first embodiment, but otherwise Fin structure SOI is adopted, which has a source and a drain formed as a silicon layer 1a on an isolator 1b in a semiconductor post (i.e. a rectangular parallelepiped shape), a channel coupling between the source and drain, and a gate wrapping the channel from the both sides thereof with an insulating film placed between the channel and the gate (see e.g. U.S. Pat. No. 5,346,834).

As shown in FIGS. 23 and 24A-24D, the silicon layer la that the substrate 1 includes is partially removed, whereby the silicon layer 1a is formed in a rectangular parallelepiped shape. On the left and right side faces of the silicon layer la are formed a control gate CG and a memory gate MG. An n type first drain and a p type second drain are formed in different planar locations in the main surface of the substrate 1, and the first and second drains are adjacent to each other.

The application of the invention to Fin structure SOI enables the reduction in leakage current because the potential of the channel is controlled from the left and right sides thereof by the control gate CG or memory gate MG. Especially, in the time of erasing data, an electronic leakage current from the channel under the memory gate MG is suppressed and as such, the gate length of the memory gate MG can be reduced.

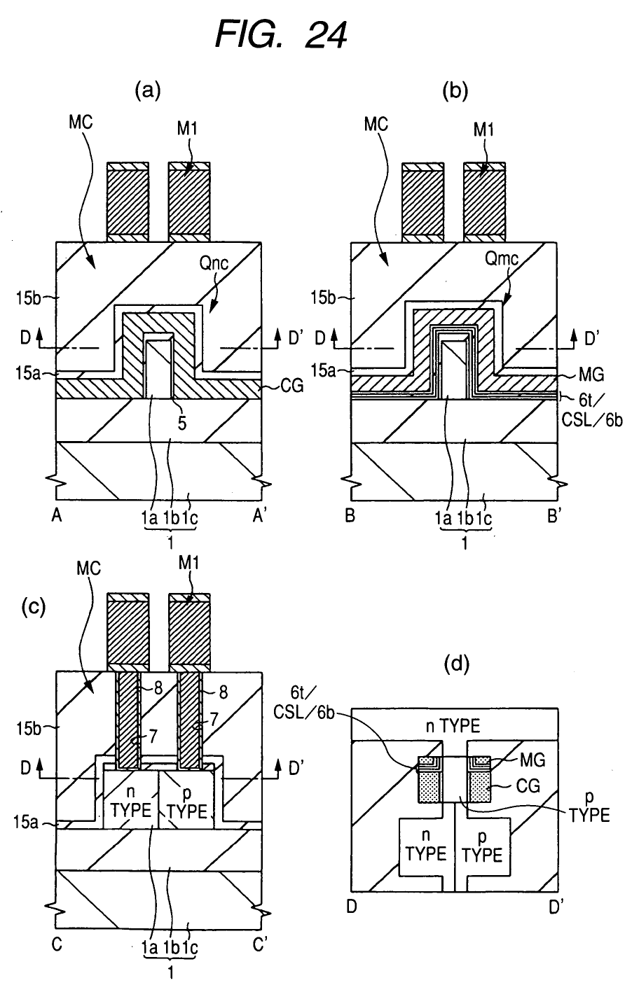

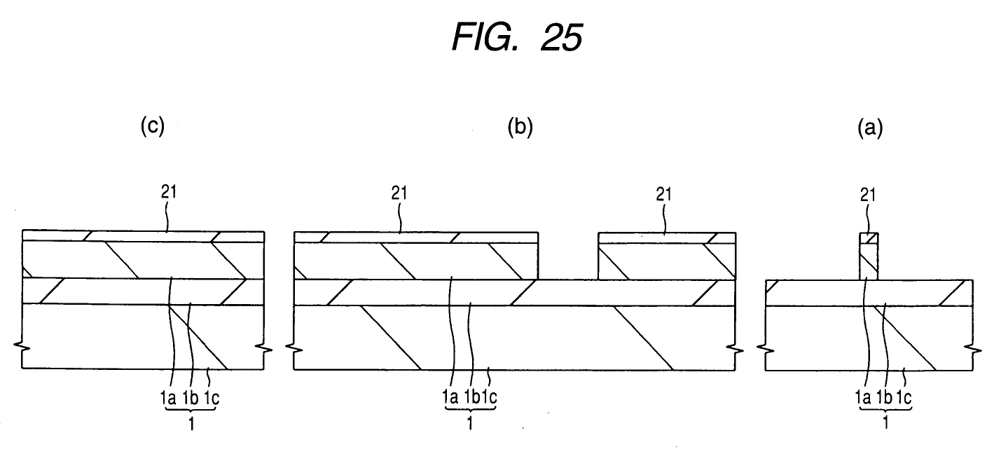

A method of manufacturing the MONOS type memory cell of Fin structure according to the fourth embodiment will be described in reference to FIGS. 25A-25C to 33A-33C in the order in which the steps thereof are carried out. Of the drawings, the drawings having a drawing number accompanied with the character “A, B or C” at its end are partial sectional views showing an important portion of the MONOS type memory cell taken along the line A-A′, E-E′ or F-F′ in FIG. 23, respectively. Also, the drawings having a drawing number accompanied with the character “B” show, in section, an important portion of an nMIS formed for a peripheral circuit.

First, the substrate 1 is prepared, as shown in FIGS. 25A-25C. The substrate 1 is an SOI substrate. Then, a silicon oxide film and a silicon nitride film are deposited on the main surface of the substrate 1 in sequence to form an insulating film 21. After that, the insulating film 21 and the silicon layer la are patterned by the lithography and etching techniques thereby to form a Fin portion basic structure composed of the silicon layer 1a shaped into the form of a semiconductor post, provided that the insulating film 21 is left on the silicon layer 1a machined into the form of a Fin. In the resulting silicon layer 1a, a source, a drain, and a channel of a memory cell are to be formed in the later steps.

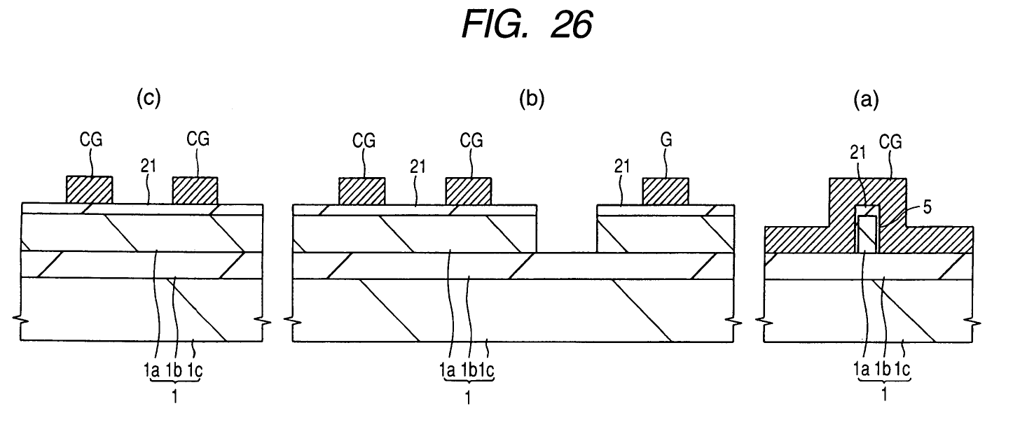

Next, as shown in FIGS. 26A-26C, the substrate 1 is subjected to oxidizing treatment, whereby a gate-insulating film 5 of e.g. silicon oxide having a thickness of 2 to 3 nm approximately is formed on the surface of the silicon layer 1a. Subsequently, a conductor film of polycrystalline silicon of low resistance is deposited on the main surface of the substrate 1 up to about 200 nm by CVD method. Then, the conductor film is patterned using the lithography and etching techniques, whereby a control gate CG and a gate G of an nMIS that a peripheral circuit includes are formed.

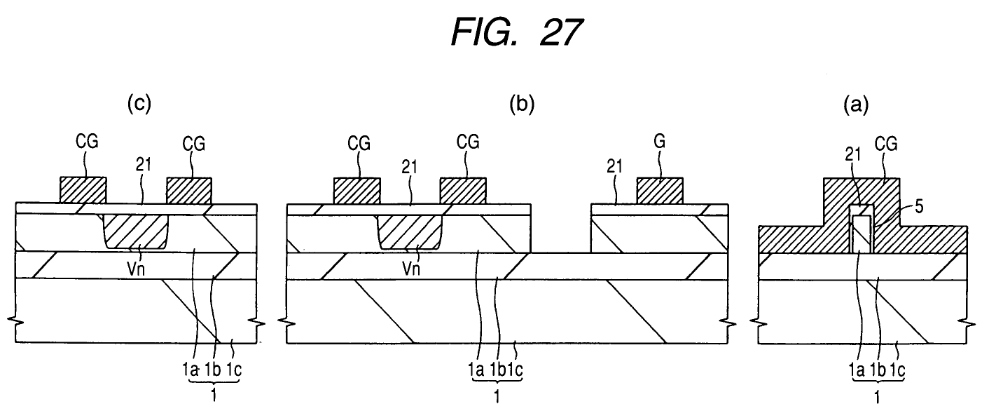

Next, as shown in FIGS. 27A-27C, using a set of the control gate CG and a resist pattern formed by the lithography technique as a mask, e.g. arsenic or phosphorus is doped into the silicon layer la by ion implantation, thereby to form an n type semiconductor region Vn to form a channel of a memory-use nMIS Qnm.

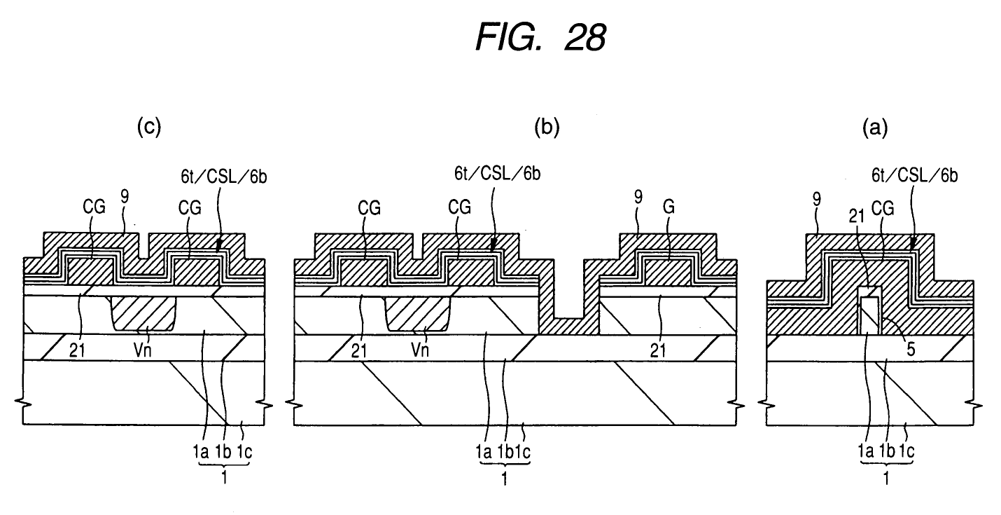

Then, as shown in FIGS. 28A-28C, on the main surface of the substrate 1 are formed, for example, an insulating film 6b of silicon oxide, a charge storage layer CSL of silicon nitride, and an insulating film 6t of silicon oxide in sequence, and then a conductor film 9 of polycrystalline silicon of low resistance used to form a memory gate is deposited thereon.

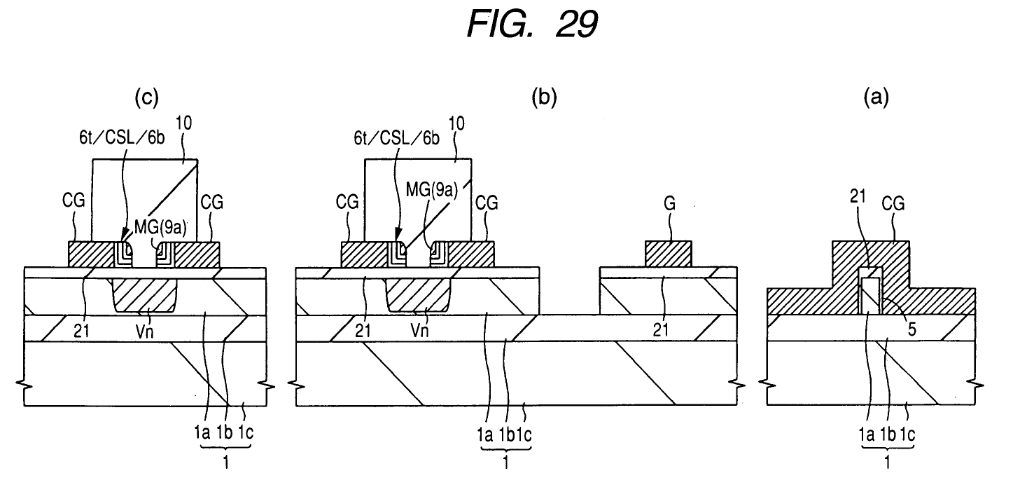

Thereafter, as shown in FIGS. 29A-29C, the conductor film 9 is etched by the anisotropic dry etching, whereby a side wall 9a is formed from the conductor film 9 on both the sides of the control gate CG. Subsequently, a resist pattern 10 used to form a memory gate is formed on the main surface of the substrate 1 by the lithography technique. After that, using the resist pattern 10 as a mask, a portion of the side wall 9a exposed from the mask is etched to form a memory gate MG (side wall 9a) on one side of the control gate CG. Then, after the resist pattern 10 is removed, the insulating films 6b, 6t and the charge storage layer CSL are etched selectively.

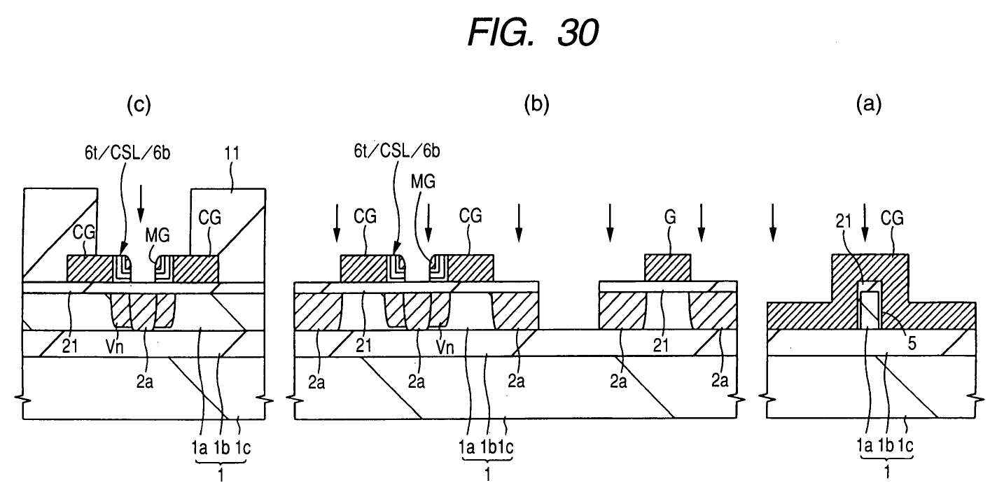

Next, as shown in FIGS. 30A-30C, a resist pattern 11 for covering the second drain-forming region is formed by the lithography technique. After that, using a set of the control gate CG, memory gate MG, the gate G of an nMIS constituting a peripheral circuit, and the resist pattern 11 as a mask, e.g. arsenic or phosphorus is doped into the silicon layer 1a by ion implantation, whereby n⁻type diffusion regions 2a are formed in the silicon layer 1a so as to self-match with the control gate CG, the memory gate MG, the gate G of the nMIS constituting a peripheral circuit.

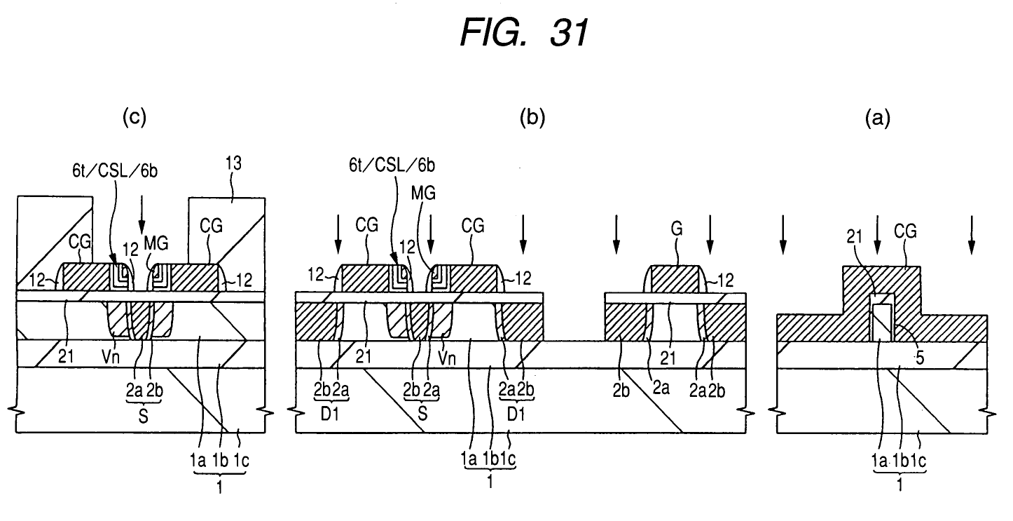

Next, the resist pattern 11 is removed as shown FIGS. 31A-31C, and then an insulating film of e.g. silicon oxide is deposited on the main surface of the substrate 1 up to a thickness of about 100 nm by CVD method. Subsequently, the insulating film is etched by anisotropic dry etching. Thus, side walls 12 are formed on the other side of the control gate CG, the memory gate MG, and both the side faces of the gate G of the nMIS constituting a peripheral circuit Then, a resist pattern 13 for covering the second drain-forming region is forming by the lithography technique. After that, using a set of the control gate CG, the memory gate MG, the gate G of the nMIS constituting a peripheral circuit, and the resist pattern 13 as a mask, e.g. arsenic or phosphorus is doped into the silicon layer 1a by ion implantation. As a result, n⁺ type diffusion regions 2b are formed in the silicon layer la so as to self-match with respect to the control gate CG, the memory gate MG, and the gate G of the nMIS constituting a peripheral circuit. Thus, the first drain D1 and source S of the memory cell MC, and the drain and source of the nMIS constituting a peripheral circuit, each composed of the n type diffusion region 2a and n⁺ type diffusion region 2b, are formed.

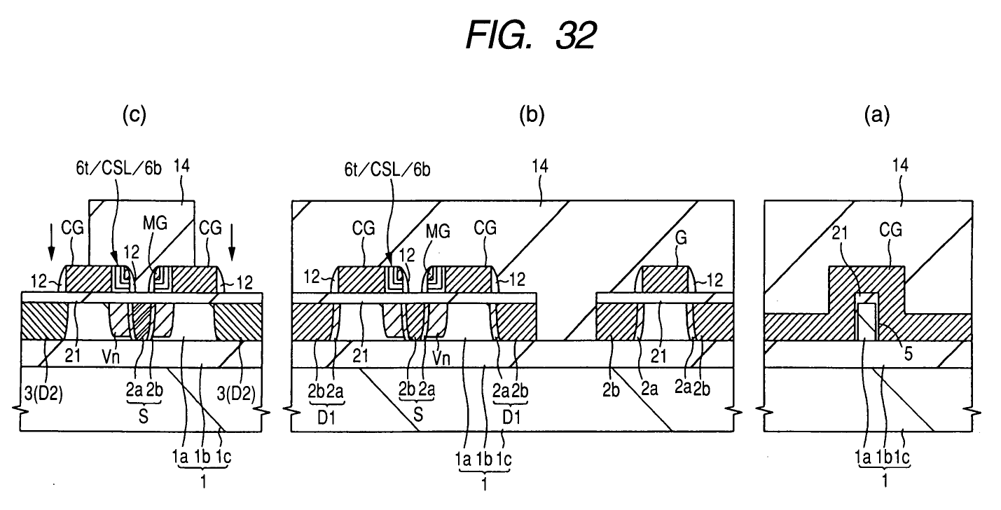

Next, as shown in FIGS. 32A-32C, the resist pattern 13 is removed, and then a resist pattern 14 for covering the first drain-forming region and the source-forming regions is formed by the lithography technique. After that, using a set of the control gate CG and the resist pattern 14 as a mask, e.g. boron or boron fluoride is doped into the silicon layer 1a by ion implantation, whereby a p⁺ type diffusion region 3 is formed in the silicon layer 1a so as to self-match with respect to the control gate CG. Thus, a second drain D2 of the memory cell MC composed of the p⁺ type diffusion region 3 is formed.

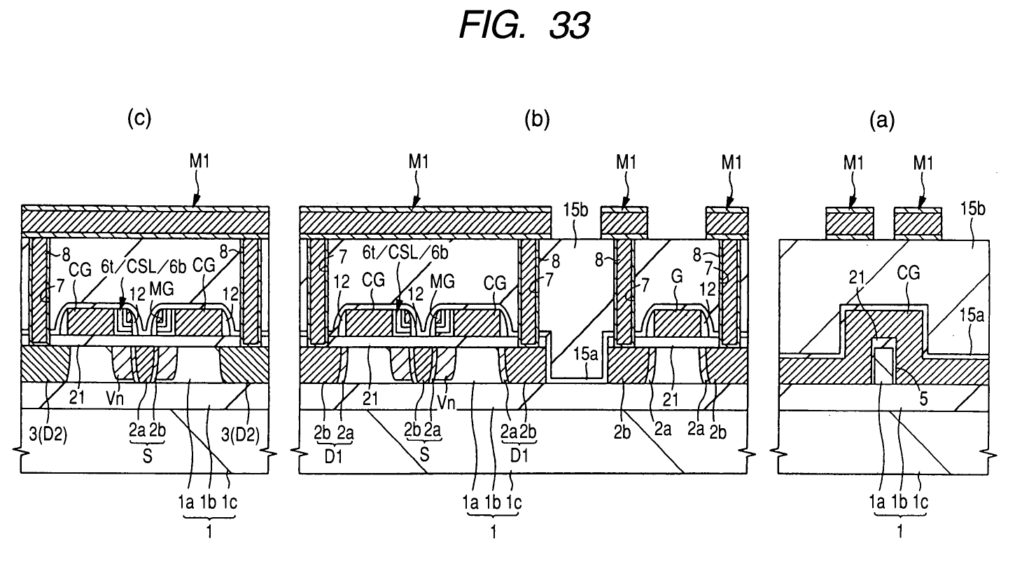

In this way, the drain D composed of the two kinds of drains, i.e. the first drain D1 and the second drain D2, and the source S, and the selection-use nMIS Qnc and the memory-use nMIS Qnm are formed, whereby a MONOS type memory cell is manufactured. After that, a wiring step the same as that performed in the first embodiment is carried out, and then a memory cell MC as shown in FIGS. 33A-33C is substantially finished.

### Fifth Embodiment

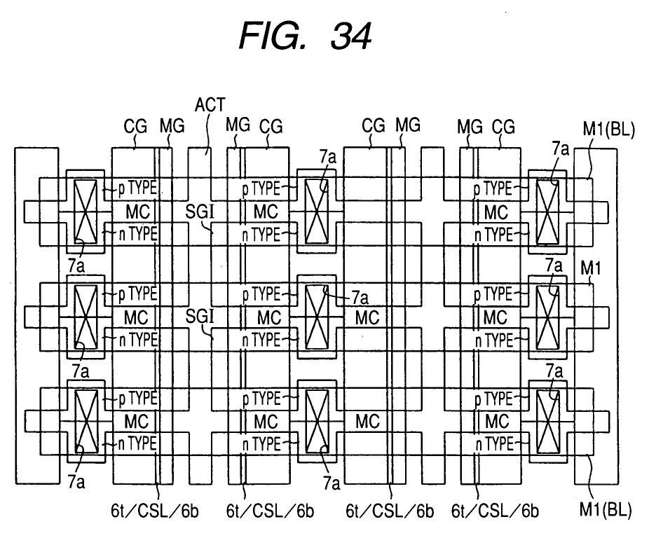

Also, in regard to a MONOS type memory cell formed in a Fin structure SOI, it is possible to form a bit line connected to the first and second drains and shared. FIG. 34 is a plan view showing an important portion of a MONOS type memory cell formed in a Fin structure SOI according to the fifth embodiment, in which the memory cell has a bit line connected to both the first and second drains and shared, and the first and second drains are arranged in planar locations adjacent to each other.

As shown in FIG. 34, in the MONOS type memory cell according to the fifth embodiment, a first drain D1 and a second drain D2 in contact with each other are formed in different planar locations in the main surface of the substrate 1, and a first layer's conductor line M1 is formed athwart both the first and second drains D1 and D2, as in the case of the second embodiment shown in FIG. 17. This allows the bit line to be shared by the selection-use nMIS Qnc and the memory-use nMIS Qnm, and therefore the pitch width of the bit line BL can be reduced.

### Sixth Embodiment

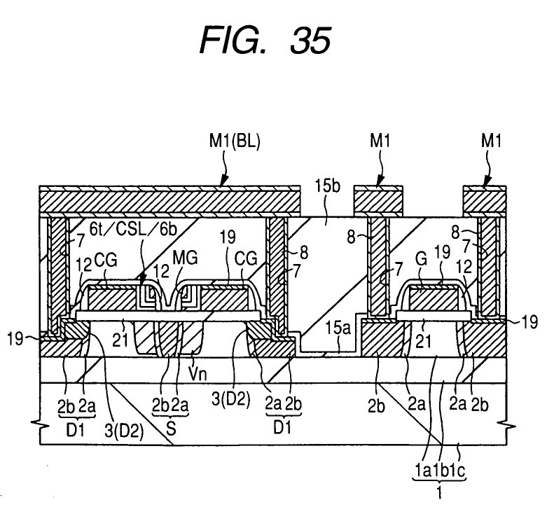

FIG. 35 is a partial sectional view of an important portion of a MONOS type memory cell formed in a Fin structure SOI according to the sixth embodiment. The MONOS type memory cell has a first drain and a second drain, which are arranged so as to be in contact with each other in the depth direction of the substrate, and a bit line connected to both the first and second drains and shared.

As shown in FIG. 35, in the MONOS type memory cell according to the sixth embodiment, the first drain D1 and second drain D2 are formed so as to be in contact with each other in the depth direction of the substrate 1, and a first layer's conductor line M1 or silicide layer 19 is formed athwart both the first and second drains D1, D2, as in the case of the third embodiment shown in FIG. 19. This allows the bit line to be shared by the selection-use nMIS Qnc and the memory-use nMIS Qnm. Thus, the following are made possible: to reduce the pitch width of the bit line BL; and to erase data with higher reliability because of the agreement between the electrons' flow path during the time of writing data and the holes' flow path during the time of erasing data.

While the invention that the inventors made has been described above on the embodiments thereof, the invention is not limited to the embodiments. It is obvious that various modifications and changes may be made without departing the subject matter of the invention.

A MONOS type memory cell according to an aspect of the invention can be applied to products for mass-production, which require both high-speed performance and power-saving performance and can be formed using the existing semiconductor manufacturing techniques.

1. A semiconductor device comprising a nonvolatile memory cell including:
a first field effect transistor formed in a first region on a main surface of a semiconductor substrate;
a second field effect transistor formed adjacent to said first field effect transistor in a second region on said main surface of said semiconductor substrate;
a first insulating film formed in said first region;
a first gate of said first field effect transistor formed in said first region and overlying said first insulating film;
a second insulating film formed in said second region and including a charge storage layer;
a second gate of said second field effect transistor formed in said second region and overlying said second insulating film;
a first diffusion region of a first conductivity type;
a second diffusion region of a second conductivity type said first and second diffusion regions respectively formed in different planar locations in a region adjacent to said first gate; and
a third diffusion region of said first conductivity type formed in a region adjacent to said second gate.

2. The semiconductor device of claim 1, wherein data is written in the memory cell by injecting electrons from said first diffusion region,
applying a relatively larger positive voltage to said second gate to create hot electrons, and
injecting the hot electrons into said charge storage layer.

3. The semiconductor device of claim 2, wherein when said data is written in said memory cell, said second diffusion region is brought to open state.

4. The semiconductor device of claim 1, wherein data is erased by injecting holes from said second diffusion region,
applying a relatively larger negative voltage to said second gate to create hot holes, and
injecting said hot holes into the charge storage layer.

5. The semiconductor device of claim 4, wherein when said data is erased, said first diffusion region is brought to open state.

6. The semiconductor device of claim 1, wherein said first and second diffusion regions are formed with an element-separating portion interposed between said first and second diffusion regions.

7. The semiconductor device of claim 1, wherein said first and second diffusion regions are formed in contact with each other.

8. The semiconductor device of claim 1, further comprising:
a first conductor line connected to said first diffusion region; and
a second conductor line connected to said second diffusion region,
wherein different voltages are applied to said first conductor line and said second conductor line respectively.

9. The semiconductor device of claim 1, further comprising a third conductor line connected to said first and second diffusion regions.

10. The semiconductor device of claim 1, wherein said semiconductor substrate is comprised of an SOI substrate.

11. A semiconductor device comprising a nonvolatile memory cell including:
a first field effect transistor formed in a first region on a main surface of said semiconductor substrate;
a second field effect transistor formed adjacent to said first field effect transistor in a second region on said main surface of said semiconductor substrate;
a first insulating film formed in said first region;
a first gate of said first field effect transistor formed in said first region and overlying said first insulating film;
a second insulating film formed in said second region and including a charge storage layer;
a second gate of said second field effect transistor, formed in said second region and overlying said second insulating film;
a first diffusion region of a first conductivity type;
a second diffusion region of a second conductivity type, said first and second diffusion regions respectively formed in a region adjacent to said first gate so as to be in contact with each other in a depth direction of said semiconductor substrate; and
a third diffusion region of said first conductivity type formed in a region adjacent to said second gate.

12. The semiconductor device of claim 11, wherein data is written in said memory cell by injecting electrons from said first diffusion region,
applying a relatively larger positive voltage to said second gate to create hot electrons, and
injecting said hot electrons into said charge storage layer.

13. The semiconductor device of claim 12, wherein when said data is written in the memory cell, said second diffusion region is brought to open state.

14. The semiconductor device of claim 11, wherein data is erased by injecting holes from said second diffusion region,
applying a relatively larger negative voltage to said second gate to create hot holes, and
injecting said hot holes into said charge storage layer.

15. The semiconductor device of claim 14, wherein when said data is erased, said first diffusion region is brought to open state.

16. The semiconductor device of claim 11, further comprising a third conductor line connected to said first and second diffusion regions.

17. The semiconductor device of claim 11, wherein said semiconductor substrate is comprised of an SOI substrate.

18. A semiconductor device comprising a nonvolatile memory cell including:
a first field effect transistor formed in a first region on a main surface of said semiconductor substrate;
a second field effect transistor formed adjacent to said first field effect transistor in a second region on said main surface of said semiconductor substrate;
a rectangular parallelepiped silicon layer formed on said semiconductor substrate;
a first insulating film formed on both side faces of said rectangular parallelepiped silicon layer in said first region;
a first gate of said first field effect transistor formed in said first region and overlying said first insulating film;
a second insulating film formed on both side faces of said rectangular parallelepiped silicon layer in said second region and including a charge storage layer;
a second gate of said second field effect transistor formed in said second region and overlying said second insulating film;
a first diffusion region of a first conductivity type;
a second diffusion region of a second conductivity type, said first and second diffusion regions respectively formed in different planar locations in a region adjacent to said first gate; and
a third diffusion region of the first conductivity type formed in a region adjacent to said second gate.

19. The semiconductor device of claim 18, wherein data is written in said memory cell by injecting electrons from said first diffusion region,
applying a relatively larger positive voltage to said second gate to create hot electrons, and
injecting said hot electrons into said charge storage layer.

20. The semiconductor device of claim 19, wherein when said data is written in said memory cell, said second diffusion region is brought to open state.

21. The semiconductor device of claim 18, wherein data is erased by injecting holes from said second diffusion region,
applying a relatively larger negative voltage to said second gate to create hot holes, and
injecting said hot holes into said charge storage layer.

22. The semiconductor device of claim 21, wherein when said data is erased, said first diffusion region is brought to open state.

23. The semiconductor device of claim 18, wherein said first and second diffusion regions are formed in contact with each other.

24. The semiconductor device of claim 18, further comprising:
a first conductor line connected to said first diffusion region; and
a second conductor line connected to said second diffusion region,
wherein different voltages are applied to said first conductor line and said second conductor line respectively.

25. The semiconductor device of claim 18, further comprising a third conductor line connected to said first and second diffusion regions.

26. The semiconductor device of claim 18, wherein said semiconductor substrate is made of an SOI substrate.

27-50. (canceled)
